(19) United States
(12) Patent Application Publication
(10) Pub. No.: US 2022/0149214 A1
(43) Pub. Date: May 12, 2022

(54) LIGHT SENSOR MODULE

(71) Applicants: LITE-ON OPTO TECHNOLOGY (CHANGZHOU) CO., LTD., Changzhou City (CN); LITE-ON TECHNOLOGY CORPORATION, Taipei City (TW)

(72) Inventors: FANG-JUNG SUN, New Taipei City (TW); Shih-Chang Hsu, Taipei City (TW); JHIH-CHENG SYU, New Taipei City (TW)

(21) Appl. No.: 17/517,750

(22) Filed: Nov. 3, 2021

(30) Foreign Application Priority Data
Nov. 11, 2020 (CN) 202011255911.0

(51) Int. Cl. H01L 31/0232; H01L 31/0203

(52) U.S. Cl. CPC H01L 31/02322; H01L 31/02327; H01L 31/0203

(57) ABSTRACT

A light sensor module is provided. The light sensor module is used to receive a first light beam and generate an electric current corresponding to an intensity of the first light beam. The light sensor module includes a substrate, a photodiode chip, and a wavelength conversion structure. The photodiode chip is disposed on the substrate. The wavelength conversion structure is disposed on the substrate, and the photodiode chip is covered by the wavelength conversion structure. The first light beam is converted into a second light beam by the wavelength conversion structure. The photodiode chip receives the second light beam, and then generates the electric current.

### CROSS-REFERENCE TO RELATED PATENT APPLICATION

This application claims the benefit of priority to China Patent Application No. 202011255911.0, filed on Nov. 11, 2020 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light sensor module, and more particularly to an ultraviolet light sensor module.

### BACKGROUND OF THE DISCLOSURE

Ultraviolet light-emitting diodes (LED) have widespread applications and are usually used as ultraviolet light sources. It is common for the ultraviolet light-emitting diode to cooperate with an ultraviolet photodiode (PD), so that an intensity of the ultraviolet light source can be detected by the ultraviolet photodiode.

A photodiode has a function of receiving photons and then converting the photons into electrons. When a light beam received by the photodiode has a strong intensity, the photodiode can generate high electric current. In other words, a light signal can be converted into an electric signal by the photodiode, and an intensity of the electric signal generated by the photodiode is directly proportional to an intensity of the light signal received by the photodiode.

Generally, a price of an ultraviolet photodiode is much higher than a price of a visible-light photodiode, which causes a price of an ultraviolet sensor module to be higher as well. Therefore, in the related art, several attempts have been made to have the visible light photodiode cooperate with the ultraviolet light-emitting diode instead of the ultraviolet photodiode, so as to reduce the cost of the ultraviolet sensor module. However, since the visible light photodiode on the market is not sensitive to ultraviolet light, the visible light photodiode has difficulty in generating the electric current which corresponds to the intensity of the ultraviolet light.

Accordingly, as the price of the ultraviolet sensor module on the market remains high, how the visible light photodiode and the ultraviolet light-emitting diodes can be used cooperatively has become an important issue in the related art.

### SUMMARY OF THE DISCLOSURE

In response to the above-referenced technical inadequacies, the present disclosure provides a light sensor module.

In one aspect, the present disclosure provides a light sensor module. The light sensor module is used to receive a first light beam and generate an electric current corresponding to an intensity of the first light beam. The light sensor module includes a substrate, a photodiode chip, and a wavelength conversion structure. The photodiode chip is disposed on the substrate. The wavelength conversion structure is disposed on the substrate, and the photodiode chip is covered by the wavelength conversion structure. The first light beam is converted into a second light beam by the wavelength conversion structure. The photodiode chip receives the second light beam and then generates the electric current.

In another aspect, the present disclosure provides an electronic device. The electronic device includes a light-emitting module and a light sensor module. The light-emitting module is used to generate a first light beam. The light sensor module is used to receive the first light beam and generate an electric current corresponding to an intensity of the first light beam. The light sensor module includes a substrate, a photodiode chip, and a wavelength conversion structure. The photodiode chip is disposed on the substrate. The wavelength conversion structure is disposed on the substrate, and the photodiode chip is covered by the wavelength conversion structure. The first light beam is converted into a second light beam by the wavelength conversion structure. The second light beam is received by the photodiode chip, and then the electric current is generated by the photodiode chip.

Therefore, by virtue of “the first light beam being converted into a second light beam by the wavelength conversion structure” and “the photodiode chip receiving the second light beam and then generating the electric current”, the cost of the light sensor module of the present disclosure can be reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a cross-sectional view of a light sensor module according to a first embodiment of the present disclosure.

FIG. 2 is a cross-sectional view of the light sensor module according to a second embodiment of the present disclosure.

FIG. 3 shows an enlarged view of part III of FIG. 2.

FIG. 4 is a cross-sectional view of the light sensor module according to a third embodiment of the present disclosure.

FIG. 5 is a cross-sectional view of the light sensor module according to a fourth embodiment of the present disclosure.

FIG. 6 is a cross-sectional view of the light sensor module according to a fifth embodiment of the present disclosure.

FIG. 7 is a cross-sectional view of the light sensor module according to a sixth embodiment of the present disclosure.

FIG. 8 is a cross-sectional view of the light sensor module according to a seventh embodiment of the present disclosure.

FIG. 9 is Fourier transform infrared spectroscopy spectra of methyl silicon A and methyl silicon B.

FIG. 10 is a cross-sectional view of an electronic device of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In order to lower the cost of an existing ultraviolet sensor module, a visible light photodiode (a photodiode chip) is cooperated with a wavelength conversion structure in the present disclosure, so as to replace an existing ultraviolet photodiode. In addition, other components are added and contents of the components are adjusted in the ultraviolet sensor module, so that a sensitivity of the visible light photodiode to ultraviolet light can be enhanced. Accordingly, the visible light photodiode can be used in the ultraviolet sensor module (or an ultraviolet sensor), and the cost of the ultraviolet sensor module can be reduced.

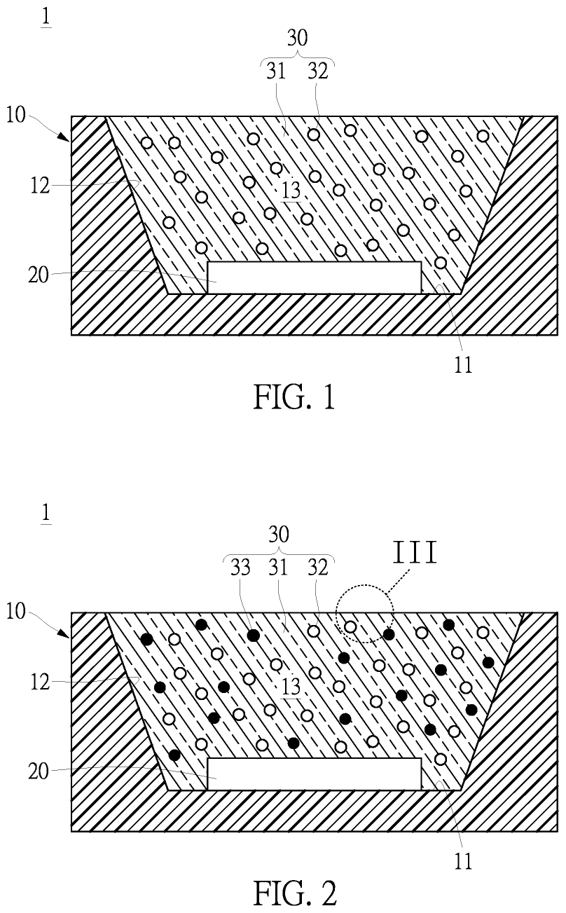

Referring to FIG. 1, a light sensor module 1 of the present disclosure includes a substrate 10, a photodiode chip 20, and a wavelength conversion structure 30. The light sensor module 1 is used to receive a first light beam and generate an electric current corresponding to an intensity of the first light beam.

The substrate 10 has a mounting surface 11 and an inner side surface 12. The mounting surface 11 and the inner side surface 12 are connected with each other, and an accommodation space 13 is defined by the mounting surface 11 and the inner side surface 12.

The photodiode chip 20 is disposed in the accommodation space 13 and on the mounting surface 11 of the substrate 10. The photodiode chip 20 is disposed between the substrate 10 and the wavelength conversion structure 30. The photodiode chip 20 is completely covered by the wavelength conversion structure 30.

The wavelength conversion structure 30 is disposed in the accommodation space 13. The wavelength conversion structure 30 can receive the first light beam and then convert the first light beam into a second light beam. The photodiode chip 20 can receive the second light beam and then generate the electric current corresponding to an intensity of the second light beam. Since an electric signal and a photo signal are directly proportional to each other, the intensity of the first light beam can be derived by measuring the electric current generated by the photodiode chip 20. Therefore, the first light beam can be detected by the light sensor module 1.

Specifically, the light sensor module 1 of the present disclosure is an ultraviolet sensor module, and the photodiode chip 20 is a visible light photodiode. Therefore, the first light beam received by the light sensor module 1 is ultraviolet light. The first light beam has a peak wavelength ranging between 10 nm to 400 nm. The first light beam (ultraviolet light) is converted into the second light beam (visible light) by the wavelength conversion structure 30, so that the photodiode chip 20 (visible light photodiode) can receive the second light beam, and then generate the electric current. The second light beam has a spectrum ranging between 400 nm and 700 nm.

A material of the wavelength conversion structure includes a fluorescent material. Ultraviolet light can be converted into visible light by the fluorescent material, so that the visible light photodiode can be used in the ultraviolet sensor module. The fluorescent material is selected from the group consisting of: a metal oxide containing rare earth elements, a metal nitride containing rare earth elements, a metal phosphide containing rare earth elements, a metal silicon oxide containing rare earth elements, a metal oxynitride containing rare earth elements, a metal oxycarbonitride containing rare earth elements, and any combination thereof.

Specifically, the fluorescent material is selected from the group consisting of: Ba_{2.0}Eu_{0.6}Mg_{3.2}Al_{30.5}Oₓ, (Ba,Sr)_{3.0}Mg_{3.2}Al_{30.5}O_{51.9}:Eu²⁺, BaMgAl₁₀O₁₇:Eu, Ba,Mg,Al₁₀O₁₇:Eu,Mn, CeMgAl₁₁O₁₉:Tb³⁺, Tb₃Al₅O₁₂:Ce³⁺, La₃Si₆N₁₁:Ce, (Ba,Sr)₂Si₅N₈:Eu, (Sr,Ca)AlSiN₃:Eu, (Sr,Ba)₁₀(PO₄)₆Cl₂:Eu, LaPO₄:Ce,Tb, (Ba,Sr,Ca)₂SiO₄:Eu²⁺, Si_{6-z}Al_{z}O_{z}N_{8-z}:Eu, and any combination thereof Here, “x” is a positive number, and “z” is a positive number less than 6.

[Control Group 1]

In order to compare the sensitivity of the light sensor module, a visible light-emitting diode is cooperated with a visible light photodiode (i.e., the photodiode chip 20 of the present disclosure), which form a light sensor module acting as Control Group 1. A visible light generated by the visible light-emitting diode is received by the visible light photodiode, and then an electric current is generated by the visible light photodiode. After experimentation, the visible light photodiode generates an electric current of 3.789 μA, which is taken as a target value of 100%.

### First Embodiment

Referring to FIG. 1, the light sensor module 1 of a first embodiment includes the substrate 10, the photodiode chip 20, and the wavelength conversion structure 30. A material of the wavelength conversion structure 30 includes an encapsulating material 31 and a fluorescent material 32. The fluorescent material 32 is uniformly dispersed in the encapsulating material 31. In the present disclosure, the encapsulating material is a light-permeable resin. In a preferable embodiment, the encapsulating material is a silicone material containing a specific functional group, such as phenyl silicone resin, methyl silicone resin, or fluorosilicone resin. In some embodiments, the encapsulating material is preferably phenyl silicone resin or methyl silicone resin; and more preferably, the encapsulating material is methyl silicone resin. When being exposed to UVC (ultraviolet light having a wavelength between 100 nm to 280 nm), the aforesaid encapsulating material has a high transmittance.

### Examples 1 and 2

The light sensor modules of Examples 1 and 2 correspond to the light sensor module of the first embodiment (FIG. 1). Referring to Table 1, different encapsulating materials are used in Examples 1 and 2, so as to show how the sensitivity of the light sensor module is influenced by different encapsulating materials. In Examples 1 and 2, the light sensor modules are exposed to ultraviolet light, and then the electric currents generated by the photodiode chips are measured. The electric currents are compared to the electric current of Control Group 1 designated as the target value of 100%.

In Examples 1 and 2, the materials of the wavelength conversion structure include the encapsulating material and the fluorescent material. The encapsulating material in Example 1 is phenyl silicone resin (such as OE-6650 sold by Dow Corning Corp.), and the encapsulating material in Example 2 is methyl silicone resin (such as OE-6351 sold by Dow Corning Corp.). The fluorescent materials in Examples 1 and 2 are the metal oxide containing rare earth metals whose chemical formula is Tb₃Al₅O₁₂:Ce³⁺ (such as TAG-T3 sold by Nemoto & Co., Ltd.). Based on a total weight of the encapsulating material used in the wavelength conversion structure being 100 phr, a content of the fluorescent material is 40 phr.

TABLE 1

| | Wavelength conversion structure | | | | |
|---|---|---|---|---|---|
| | Encap- | | Content of | Photodiode chip | |
| | sulating | Fluorescent | fluorescent | Electric | Target |
| | material | material | material | current | value |
| Example | Phenyl | Tb₃Al₅O₁₂:Ce³⁺ | 40 phr | 1.001 μA | 26.4% |
| 1 | silicone resin | | | | |
| Example | Methyl | Tb₃Al₅O₁₂:Ce³⁺ | 40 phr | 2.038 μA | 53.8% |
| 2 | silicone resin | | | | |

From results of Table 1, the sensitivity of the light sensor module can be enhanced by using silicones containing specific functional groups (phenyl silicone resin or methyl silicone resin) as the encapsulating material. In addition, compared to phenyl silicone resin (Example 1), methyl silicone resin (Example 2) can further enhance the sensitivity of the light sensor module.

### Examples 3 to 11

The light sensor modules of Examples 3 to 11 correspond to the light sensor module of the first embodiment (FIG. 1). Referring to Table 2, different contents of the fluorescent materials are used in Examples 3 to 11, so as to show how the sensitivity of the light sensor module is influenced by different contents of the fluorescent materials. In Examples 3 to 11, the light sensor modules are exposed to ultraviolet light, and then the electric currents generated by the photodiode chip are measured. The electric currents are compared to the electric current of Control Group 1 designated as the target value of 100%.

In Examples 3 to 11, the materials of the wavelength conversion structure include the encapsulating material and the fluorescent material. While the encapsulating material is methyl silicone resin, the fluorescent material is Tb₃Al₅O₁₂:Ce³⁺. The content of the fluorescent material is based on a total weight of the encapsulating material used in the wavelength conversion structure being 100 phr.

TABLE 2

| | Wavelength conversion structure | | | | |
|---|---|---|---|---|---|
| | Encap- | | Content of | Photodiode chip | |
| | sulating | Fluorescent | fluorescent | Electric | Target |
| | material | material | material | current | value |
| Example | Methyl | Tb₃Al₅O₁₂:Ce³⁺ | 0 phr | 0.124 μA | 3.3% |
| 3 | silicone resin | | | | |
| Example | Methyl | Tb₃Al₅O₁₂:Ce³⁺ | 2.5 phr | 0.932 μA | 24.6% |
| 4 | silicone resin | | | | |
| Example | Methyl | Tb₃Al₅O₁₂:Ce³⁺ | 5.0 phr | 1.727 μA | 45.6% |
| 5 | silicone resin | | | | |
| Example | Methyl | Tb₃Al₅O₁₂:Ce³⁺ | 10 phr | 2.418 μA | 63.8% |
| 6 | silicone resin | | | | |
| Example | Methyl | Tb₃Al₅O₁₂:Ce³⁺ | 15 phr | 2.686 μA | 70.9% |
| 7 | silicone resin | | | | |
| Example | Methyl | Tb₃Al₅O₁₂:Ce³⁺ | 20 phr | 2.495 μA | 65.8% |
| 8 | silicone resin | | | | |
| Example | Methyl | Tb₃Al₅O₁₂:Ce³⁺ | 40 phr | 2.083 μA | 55.0% |
| 9 | silicone resin | | | | |
| Example | Methyl | Tb₃Al₅O₁₂:Ce³⁺ | 60 phr | 1.748 μA | 46.1% |
| 10 | silicone resin | | | | |
| Example | Methyl | Tb₃Al₅O₁₂:Ce³⁺ | 80 phr | 1.414 μA | 37.3% |
| 11 | silicone resin | | | | |

From results of Table 2, the sensitivity of the light sensor module to ultraviolet light is influenced by the contents of the fluorescent material. In some embodiments, based on the total weight of the encapsulating material used in the wavelength conversion structure being 100 phr, when the content of the fluorescent material ranges from 5 phr to 80 phr, the sensitivity of the light sensor module can be enhanced. Preferably, based on the total weight of the encapsulating material used in the wavelength conversion structure being 100 phr, the content of the fluorescent material ranges from 7 phr to 40 phr. More preferably, based on the total weight of the encapsulating material used in the wavelength conversion structure being 100 phr, the content of the fluorescent material ranges from 10 phr to 40 phr. Much more preferably, based on the total weight of the encapsulating material used in the wavelength conversion structure being 100 phr, the content of the fluorescent material ranges from 12 phr to 30 phr.

### Second Embodiment

Referring to FIG. 2, the light sensor module 1 of the second embodiment is similar to the light sensor module 1 of the first embodiment (FIG. 1). The difference is that the material of the wavelength conversion structure 30 in the second embodiment further includes a silicone powder 33. The silicone powder 33 is uniformly dispersed in the encapsulating material 31.

A microstructure 302 is formed on a surface 301 of the wavelength conversion structure 30 due to an addition of the silicone powder 33. The microstructure 302 provides an antireflective effect. Referring to FIG. 3, microscopically, the microstructure 302 is formed on the surface 301 of the wavelength conversion structure 30 by extending along a depth direction H. A refractivity of the microstructure 302 changes along the depth direction H. When a light beam enters the microstructure 302, a total internal reflection may occur, which increases the amount of the light beam passing through the microstructure 302.

### Example 12 and Comparative Example 1

The light sensor module of Example 12 corresponds to the light sensor module of the second embodiment (FIG. 2). The light sensor module of Comparative Example 1 is similar to the light sensor module of Example 12. The difference is that the silicone powder is absent from the material of the wavelength conversion structure in Comparative Example 1, and the material of the wavelength conversion structure in Comparative Example 1 further includes ceramic silicon oxide powder.

Referring to Table 3, the encapsulating materials in Example 12 and Comparative Example 1 are methyl silicone resin. The fluorescent materials in Example 12 and Comparative Example 1 are Tb₃Al₅O₁₂:Ce³⁺. Based on a total weight of the encapsulating material used in the wavelength conversion structure being 100 phr, the content of the fluorescent material is 15 phr. Based on a total weight of the encapsulating material used in the wavelength conversion structure being 100 phr, the wavelength conversion structure in Example 12 contains 60 phr of the silicone powder (such as TS120 sold by Shin-Etsu Chemical Co., Ltd.). Based on a total weight of the encapsulating material used in the wavelength conversion structure being 100 phr, the wavelength conversion structure in Comparative Example 1 contains 10 phr of the ceramic silicon oxide powder. In Example 12 and Comparative Example 1, the light sensor modules are exposed to ultraviolet light, and then the electric currents generated by the photodiode chips are measured. The electric currents are compared to the electric current of Control Group 1 designated as the target value of 100%.

TABLE 3

| | Wavelength conversion structure | | | | |
|---|---|---|---|---|---|
| | Encap- | | Silicon- | Photodiode chip | |
| | sulating | Fluorescent | contained | Electric | Target |
| | material | material | Powder | current | value |
| Example | Methyl | Tb₃Al₅O₁₂:Ce³⁺ | Silicone | 2.833 | 74.8% |
| 12 | silicone resin | | powder | μA | |
| Com- | Methyl | Tb₃Al₅O₁₂:Ce³⁺ | Ceramic | 2.475 | 65.3% |
| parative | silicone resin | | silicon | μA | |
| Example 1 | | | oxide | | |
| | | | powder | | |

From results of Table 3, the sensitivity of the light sensor module is influenced by the addition of the silicone powder or the ceramic silicon dioxide powder.

The light sensor modules in Example 7, Example 12 and Comparative Example 1 have similar structures and contents. The difference is that: the silicone powder and the ceramic silicone oxide powder are absent from the material of the wavelength conversion structure in Example 7; the material of the wavelength conversion structure in Example 12 includes the silicone powder; and the material of the wavelength conversion structure in Comparative Example 1 includes the ceramic silicone oxide powder.

From results of Tables 2 and 3, when the silicone powder and the ceramic silicone oxide powder are absent from the wavelength conversion structure, the electric current generated by the photodiode chip reaches 70.9% of the target value (Example 7). When the silicone powder is present in the wavelength conversion structure, the electric current generated by the photodiode chip reaches 74.8% of the target value (Example 12). Whereas, when the ceramic silicone oxide powder is present in the wavelength conversion structure, the electric current generated by the photodiode chip is decreased to 65.3% of the target value (Comparative Example 1).

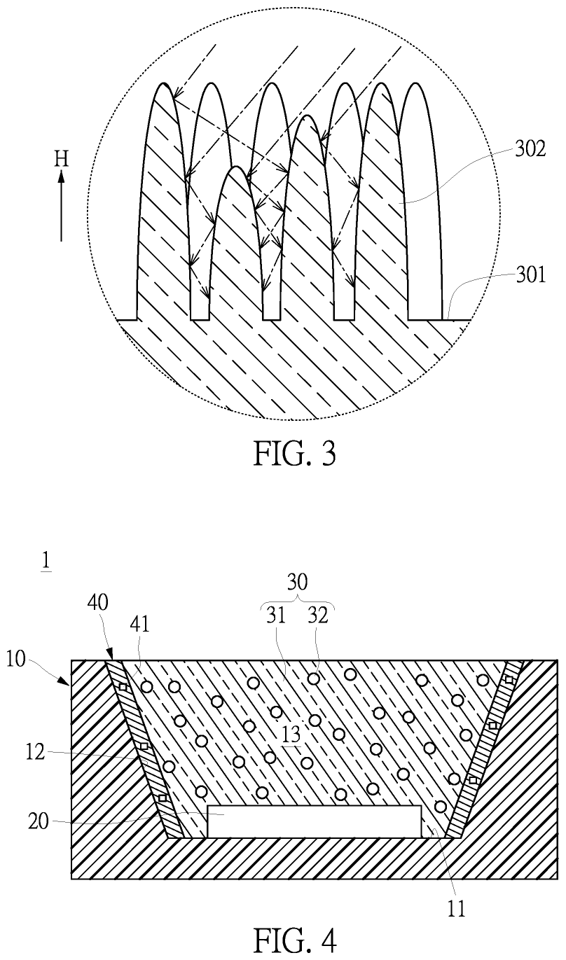

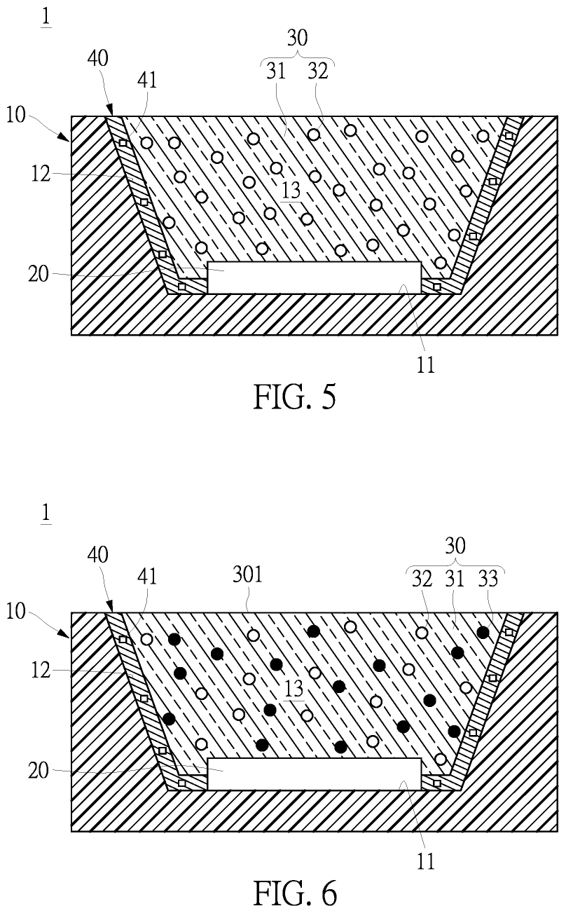

Referring to FIGS. 4 and 5, in some embodiments, the light sensor module 1 further includes a reflective layer 40. The reflective layer 40 is disposed on the mounting surface 11 or the inner side surface 12 of the substrate 10. The reflective layer 40 is disposed between the substrate 10 and the wavelength conversion structure 30.

The reflective layer 40 can reflect light beams, so that a probability of the first and the second light beams being received by the photodiode chip 20 can be increased, thereby enhancing the sensitivity of the light sensor module 1. A material of the reflective layer 40 includes an encapsulating material and visible light reflective fillers 41. The visible light reflective fillers 41 are dispersed in the reflective layer 40. The addition of the visible light reflective fillers 41 can increase a probability of the second light beam being received by the photodiode chip 20, so that the sensitivity of the light sensor module 1 can be enhanced.

Specifically, the visible light reflective fillers 41 are selected from the group consisting of: titanium dioxide, aluminum oxide, zinc oxide, silicon dioxide, boron nitride, and any combination thereof. Based on a total weight of the encapsulating material used in the reflective layer 40 being 100 phr, a content of the visible light reflective fillers 41 ranges from 20 phr to 50 phr.

### Third Embodiment

Referring to FIG. 4, the light sensor module 1 of the third embodiment is similar to the light sensor module 1 of the first embodiment (FIG. 1). The difference is that the light sensor module 1 of the third embodiment further includes the reflective layer 40. The reflective layer 40 is disposed on the inner side surface 12 of the substrate 10, and the reflective layer 40 is disposed between the substrate 10 and the wavelength conversion structure 30.

### Fourth Embodiment

Referring to FIG. 5, the light sensor module 1 of the fourth embodiment is similar to the light sensor module 1 of the first embodiment (FIG. 1). The difference is that the light sensor module 1 of the fourth embodiment further includes the reflective layer 40. The reflective layer 40 is disposed on both the mounting surface 11 and the inner side surface 12. The reflective layer 40 is disposed between the substrate 10 and the wavelength conversion structure 30.

### Examples 13 and 14

The light sensor module of Example 13 corresponds to the light sensor module of the third embodiment (FIG. 4). The light sensor module of Example 14 corresponds to the light sensor module of the fourth embodiment (FIG. 5). Referring to Table 4, areas of the reflective layers disposed onto the substrate in Examples 13 and 14 are different, so as to show how the sensitivity of the light sensor module is influenced by the areas of the reflective layers being disposed differently. In Examples 13 and 14, the light sensor modules are exposed to ultraviolet light, and then the electric currents generated by the photodiode chips are measured. The electric currents are compared to the electric current of Control Group 1 designated as the target value of 100%.

In Examples 13 and 14, the materials of the wavelength conversion structure include the encapsulating material and the fluorescent material. The encapsulating materials are methyl silicone resin. The fluorescent materials are Tb₃Al₅O₁₂:Ce³⁺. Based on a total weight of the encapsulating material used in the wavelength conversion structure being 100 phr, the content of the fluorescent material is 15 phr. The reflective layers include the visible light reflective fillers. The visible light reflective fillers are titanium dioxide.

TABLE 4

| | Wavelength conversion structure | | | | |
|---|---|---|---|---|---|
| | | | Content of | Photodiode chip | |
| | Encapsulating | Fluorescent | fluorescent | Electric | Target |
| | material | material | material | current | value |
| Example | Methyl | Tb₃Al₅O₁₂:Ce³⁺ | 15 phr | 2.855 μA | 75.3% |
| 13 | silicone resin | | | | |
| Example | Methyl | Tb₃Al₅O₁₂:Ce³⁺ | 15 phr | 3.037 μA | 80.2% |
| 14 | silicone resin | | | | |

From results of Table 4, the larger the area of the reflective layer disposed onto the substrate is, the higher the sensitivity of the light sensor module is.

It should be noted that the light sensor modules in Examples 7, 13, and 14 have similar structures and contents. The difference is that: no reflective layer is disposed onto the substrate in Example 7; the reflective layer is disposed onto the inner side surface in Example 13; and the reflective layer is disposed onto both the mounting surface and the inner side surface in Example 14.

From results of Tables 3 and 4, the electric current generated by the photodiode chip in Example 7 reaches 70.9% of the target value, the electric current generated by the photodiode chip in Example 13 reaches 75.3% of the target value, and the electric current generated by the photodiode chip in Example 14 reaches 80.2% of the target value. Therefore, due to the reflective layer, the sensitivity of the light sensor module can be enhanced to reach more than or equal to 72% of the target value. In addition, the reflective layer can be disposed on the mounting surface or the inner side surface optionally. In a preferable embodiment, when the reflective layer is disposed on both the mounting surface and the inner side surface, the sensitivity of the light sensor module can be enhanced to reach more than or equal to 76% of the target value.

### Fifth Embodiment

Referring to FIG. 6, the light sensor module 1 of the fifth embodiment is similar to the light sensor module 1 of the fourth embodiment (FIG. 5). The difference is that, in addition to the encapsulating material 31 and the fluorescent material 32, the material of the wavelength conversion structure of the fifth embodiment further includes the silicone powder 33. The silicone powder 33 is uniformly dispersed in the encapsulating material 31. Therefore, the microstructure 302 (as shown in FIG. 3) is formed on the surface 301 of the wavelength conversion structure 30 in the fifth embodiment.

### Examples 15 to 19

The light sensor modules of Examples 15 to 19 correspond to the light sensor module of the fifth embodiment (FIG. 6). Referring to Table 5, the wavelength conversion structures in Examples 15 to 19 contain different contents of the silicone powder, so as to show how the sensitivity of the light sensor module is influenced by different contents of the silicone powder. In Examples 15 to 19, the light sensor modules are exposed to ultraviolet light, and then the electric currents generated by the photodiode chip are measured. The electric currents are compared to the electric current of Control Group 1 designated as the target value of 100%.

In Examples 15 to 19, the materials of the wavelength conversion structure include the encapsulating material, the fluorescent material, and the silicone powder. The encapsulating materials are methyl silicone resin. The fluorescent materials are Tb₃Al₅O₁₂:Ce³⁺. The content of the fluorescent material is based on the total weight of the encapsulating material used in the wavelength conversion structure being 100 phr. The content of the silicone powder is based on the total weight of the encapsulating material used in the wavelength conversion structure being 100 phr.

TABLE 5

| | Wavelength conversion structure | | | | Photodiode chip | |
|---|---|---|---|---|---|---|
| | Encapsulating | Fluorescent | Content of | Content of | Electric | Target |
| | material | material | fluorescent material | silicone powder | current | value |
| Example 15 | Methyl silicone | Tb₃Al₅O₁₂:Ce³⁺ | 15 phr | 20 phr | 2.819 μA | 74.4% |
| | resin | | | | | |
| Example 16 | Methyl silicone | Tb₃Al₅O₁₂:Ce³⁺ | 15 phr | 40 phr | 2.873 μA | 75.8% |
| | resin | | | | | |
| Example 17 | Methyl silicone | Tb₃Al₅O₁₂:Ce³⁺ | 15 phr | 60 phr | 3.193 μA | 84.3% |
| | resin | | | | | |
| Example 18 | Methyl silicone | Tb₃Al₅O₁₂:Ce³⁺ | 15 phr | 80 phr | 3.226 μA | 85.1% |
| | resin | | | | | |
| Example 19 | Methyl silicone | Tb₃Al₅O₁₂:Ce³⁺ | 15 phr | 100 phr | 3.133 μA | 82.7% |
| | resin | | | | | |

From results in Table 5, the sensitivity of the light sensor module is influenced by different contents of the silicone powder. Based on the total weight of the encapsulating material used in the wavelength conversion structure being 100 phr, when the content of the silicone powder is more than or equal to 40 phr, the electric current generated by the photodiode chip can reach more than or equal to 75% of the target value. Preferably, when the content of the silicone powder ranges from 50 phr to 90 phr, the electric current generated by the photodiode chip can reach more than or equal to 80% of the target value. Preferably, when the content of the silicone powder ranges from 60 phr to 80 phr, the electric current generated by the photodiode chip can reach more than or equal to 82% of the target value.

From results in Tables 4 and 5, the electric current generated by the photodiode chip in Example 14 can reach more than or equal to 80.2% of the target value, and the electric current generated by the photodiode chip in Example 17 can reach more than or equal to 84.3% of the target value. Therefore, due to the addition of the silicone powder, the sensitivity of the light sensor module can be enhanced to reach more than or equal to 82% of the target value.

[Control Group 2]

Different fluorescent materials have different spectrums. Therefore, an ultraviolet light-emitting diode is cooperated with an ultraviolet photodiode, which forms a light sensor module acting as Control Group 2, so as to compare the sensitivity of the light sensor module influenced by different fluorescent materials. An ultraviolet light generated by the ultraviolet light-emitting diode is received by the ultraviolet photodiode, and then an electric current is generated by the ultraviolet photodiode. After experiments, the ultraviolet photodiode generates an electric current of 14.59 μA, which is taken as a target value of 100%.

### Examples 20 to 32

Referring to Table 6, various fluorescent materials are excited by ultraviolet light in Examples 20 to 32. The fluorescent materials are respectively exposed to ultraviolet light to generate excited light beams. Spectrums of the excited light beams are analyzed, and peak wavelengths of the excited light beams (abbreviated as peak wavelength) are measured. The excited light beam is received by a visible light photodiode chip, and then an electric current is generated by the visible light photodiode chip. The electric current is compared to the electric current of Control Group 2 designated as the target value of 100%.

TABLE 6

| | Fluorescent material | | Photodiode chip | |
|---|---|---|---|---|
| | | Peak | Electric | Target |
| | Chemical formula | wavelength | current | value |
| Example | Ba_{2.0}Eu_{0.6}Mg_{3.2}Al_{30.5}Oₓ | 453 nm | 7.13 μA | 48.9% |
| 20 | | | | |
| Example | (Ba,Sr)_{3.0}M_{g3.2}Al_{30.5}O_{51.9}:Eu²⁺ | 454 nm | 8.02 μA | 55.0% |
| 21 | | | | |
| Example | (Sr,Ba)₁₀(PO₄)₆Cl₂:Eu | 465 nm | 0.31 | 70.7% |
| 22 | | | μA | |
| Example | Ba,Mg,Al₁₀O₁₇:Eu,Mn | 516 nm | 9.45 μA | 64.8% |
| 23 | | | | |
| Example | Oxycarbidonitride | 536 nm | 9.43 μA | 64.6% |
| 24 | | | | |
| Example | CeMgAl₁₁O₁₉:Tb³⁺ | 542 nm | 15.05 | 103.2% |
| 25 | | | μA | |
| Example | LaPO₄:Ce,Tb | 543 nm | 14.34 | 98.3% |
| 26 | | | μA | |
| Example | Si_{6-z}Al_{z}O_{z}N_{8-z}:Eu | 545 nm | 11.43 | 78.3% |
| 27 | | | μA | |
| Example | La₃Si₆N₁₁:Ce | 547 nm | 12.57 | 86.2% |
| 28 | | | μA | |
| Example | (Ba,Sr,Ca)₂SiO₄:Eu²⁺ | 565 nm | 15.34 | 105.1% |
| 29 | | | μA | |
| Example | Tb₃Al₅O₁₂:Ce³⁺ | 567 nm | 14.64 | 100.3% |
| 30 | | | μA | |
| Example | (Ba,Sr)₂Si₅N₈:Eu | 599 nm | 13.14 | 90.1% |
| 31 | | | μA | |
| Example | (Sr,Ca)AlSiN₃:Eu | 647 nm | 9.08 μA | 62.2% |
| 32 | | | | |

From results in Table 6, the aforesaid fluorescent materials can convert ultraviolet light (the first light beam) into visible light (the second light beam). Different fluorescent materials allow the visible light (the second light beam) to have different spectrums. When the peak wavelength of the fluorescent material is between 450 nm to 650 nm, the photodiode chip can reach 45% to 100% of the target value. Preferably, when the peak wavelength of the fluorescent material is between 453 nm to 647 nm, the photodiode chip can reach 45% to 100% of the target value. More preferably, when the peak wavelength of the fluorescent material is between 465 nm to 625 nm, the photodiode chip can reach 70% to 100% of the target value.

### Examples 33 to 39

The light sensor modules in Examples 33 to 39 correspond to the light sensor module of the fifth embodiment (FIG. 6). Referring to Table 7, another kind of the fluorescent material, i.e., (Ba,Sr)₂Si₅N₈:Eu, is used in Examples 33 to 39 to replace the fluorescent material used in Examples 1 to 19. Further, contents of the fluorescent materials in Examples 33 to 39 are different from each other, so as to show how the sensitivity of the light sensor module is influenced by the different contents of the fluorescent materials. In Examples 33 to 39, the light sensor modules are exposed to ultraviolet light, and then the electric currents generated by the photodiode chip are measured. The electric currents are compared to the electric current of Control Group 1 designated as the target value of 100%.

In Examples 33 to 39, the materials of the wavelength conversion structure include the encapsulating material, the fluorescent material, and the silicone powder. The encapsulating materials are methyl silicone resin. The fluorescent material is (Ba,Sr)₂Si₅N₈:Eu. The content of the fluorescent material is based on the total weight of the encapsulating material used in the wavelength conversion structure being 100 phr. The content of the silicone powder is based on the total weight of the encapsulating material used in the wavelength conversion structure being 100 phr.

TABLE 7

| | Wavelength conversion structure | | | | Photodiode chip | |
|---|---|---|---|---|---|---|
| | Encapsulating | Fluorescent | Content of | Content of | Electric | Target |
| | material | material | fluorescent material | silicone powder | current | value |
| Example 33 | Methyl silicone | (Ba,Sr)₂Si₅N₈:Eu | 2.5 phr | 80 phr | 1.326 μA | 35.0% |
| | resin | | | | | |
| Example 34 | Methyl silicone | (Ba,Sr)₂Si₅N₈:Eu | 5.0 phr | 80 phr | 2.203 μA | 58.1% |
| | resin | | | | | |
| Example 35 | Methyl silicone | (Ba,Sr)₂Si₅N₈:Eu | 10 phr | 80 phr | 3.095 μA | 81.7% |
| | resin | | | | | |
| Example 36 | Methyl silicone | (Ba,Sr)₂Si₅N₈:Eu | 15 phr | 80 phr | 3.371 μA | 89.0% |
| | resin | | | | | |
| Example 37 | Methyl silicone | (Ba,Sr)₂Si₅N₈:Eu | 20 phr | 80 phr | 3.382 μA | 89.3% |
| | resin | | | | | |
| Example 38 | Methyl silicone | (Ba,Sr)₂Si₅N₈:Eu | 40 phr | 80 phr | 2.831 μA | 74.7% |
| | resin | | | | | |
| Example 39 | Methyl silicone | (Ba,Sr)₂Si₅N₈:Eu | 60 phr | 80 phr | 2.061 μA | 54.4% |
| | resin | | | | | |

From results of Table 7, the sensitivity of the light sensor module is influenced by different kinds of fluorescent materials. In some embodiments, based on the total weight of the encapsulating material used in the wavelength conversion structure being 100 phr, the content of the fluorescent material ranges from 5 phr to 80 phr. Preferably, based on the total weight of the encapsulating material used in the wavelength conversion structure being 100 phr, the content of the fluorescent material ranges from 7 phr to 40 phr. More preferably, based on the total weight of the encapsulating material used in the wavelength conversion structure being 100 phr, the content of the fluorescent material ranges from 10 phr to 40 phr. Much more preferably, based on the total weight of the encapsulating material used in the wavelength conversion structure being 100 phr, the content of the fluorescent material ranges from 12 phr to 30 phr.

From results of Tables 5 and 7, the electric currents generated by the photodiode chip in Example 18 reaches 85.1% of the target value, and the electric currents generated by the photodiode chip in Example 37 reaches 89.3% of the target value. Accordingly, when the peak wavelength of the fluorescent material is between 500 nm to 620 nm, the photodiode chip can reach 75% to 100% of the target value. Preferably, when the peak wavelength of the fluorescent material is between 550 nm to 620 nm, the photodiode chip can reach 80% to 100% of the target value. More preferably, when the peak wavelength of the fluorescent material is between 570 nm to 610 nm, the photodiode chip can reach 88% to 100% of the target value.

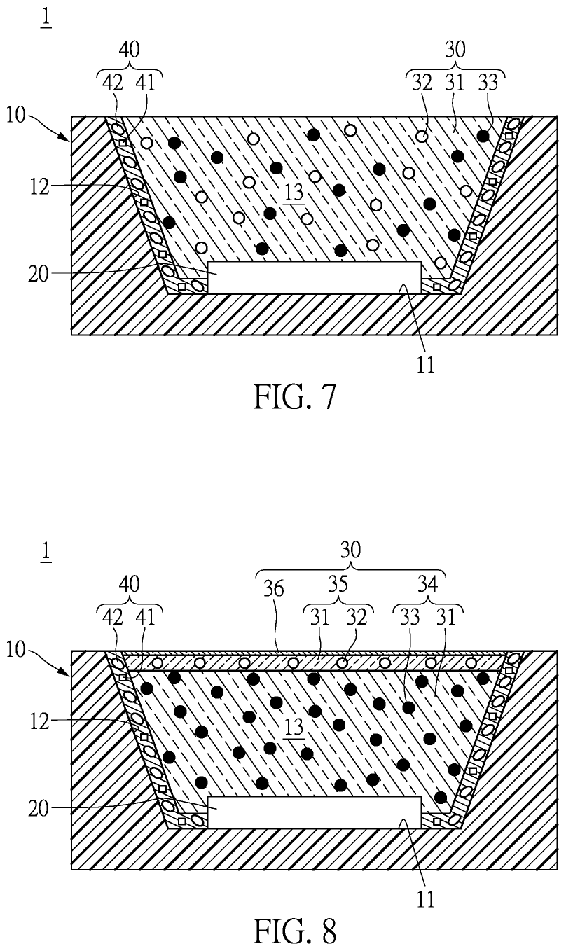

Referring to FIG. 7, in some embodiments, in addition to the visible light reflective fillers 41, the material of the reflective layer 40 can further include ultraviolet reflective fillers 42. The ultraviolet reflective fillers 42 can increase a probability of the first light beam being converted into the second light beam by the fluorescent material 32, so that the sensitivity of the light sensor module 1 can be enhanced.

### Sixth Embodiment

Referring to FIG. 7, the light sensor module 1 of the sixth embodiment is similar to the light sensor module 1 of the fifth embodiment (FIG. 6). The difference is that the material of the reflective layer 40 of the sixth embodiment further includes the ultraviolet reflective fillers 42. The ultraviolet reflective fillers 42 are uniformly dispersed in the reflective layer 40.

Specifically, the ultraviolet reflective fillers 42 are selected from the group consisting of: polytetrafluoroethene, zirconium dioxide, aluminum nitride, and any combination thereof. Based on the total weight of the encapsulating material used in the reflective layer 40 being 100 phr, a content of the ultraviolet reflective fillers 42 ranges from 10 phr to 80 phr.

### Example 40

The light sensor module of Example 40 corresponds to the light sensor module of the sixth embodiment (FIG. 7). Referring to Table 8, the reflective layer of Example 40 further includes the ultraviolet reflective fillers. The ultraviolet reflective fillers are polytetrafluoroethene (L206). Based on the total weight of the encapsulating material used in the reflective layer being 100 phr, a content of the ultraviolet reflective fillers is 80 phr. In Example 40, the light sensor module is exposed to ultraviolet light, and then the electric current generated by the photodiode chip is measured. The electric current is compared to the electric current of Control Group 1 designated as the target value of 100%.

In Example 40, the material of the wavelength conversion structure includes the encapsulating material, the fluorescent material, and the silicone powder. The encapsulating material is methyl silicone resin. The fluorescent material is Tb₃Al₅O₁₂:Ce³⁺. Based on the total weight of the encapsulating material used in the wavelength conversion structure being 100 phr, the content of the fluorescent material is 15 phr, and the content of the silicone powder is 80 phr. The material of the reflective layer includes the visible light reflective fillers (titanium dioxide) and the ultraviolet reflective fillers (polytetrafluoroethane) Based on the total weight of the encapsulating material used in the wavelength conversion structure being 100 phr, the content of the visible light reflective fillers is 15 phr, and the content of the ultraviolet reflective fillers is 80 phr.

TABLE 8

| | Wavelength conversion structure | | | | | |
|---|---|---|---|---|---|---|
| | | | Content of | Content of | Photodiode chip | |
| | Encapsulating | Fluorescent | fluorescent | silicone | Electric | Target |
| | material | material | material | powder | current | value |
| Example | Methyl | Tb₃Al₅O₁₂:Ce³⁺ | 15 phr | 80 phr | 3.500 | 92.4% |
| 40 | silicone | | | | μA | |
| | resin | | | | | |

According to results of Table 8, the sensitivity of the light sensor module can be enhanced by an addition of the ultraviolet reflective fillers. In some embodiments, based on the total weight of the encapsulating material used in the wavelength conversion structure being 100 phr, the content of the ultraviolet reflective fillers is larger than or equal to 40 phr. Preferably, based on the total weight of the encapsulating material used in the wavelength conversion structure being 100 phr, the content of the ultraviolet reflective fillers ranges from 50 phr to 90 phr. More preferably, based on the total weight of the encapsulating material used in the wavelength conversion structure being 100 phr, the content of the ultraviolet reflective fillers ranges from 60 phr to 85 phr.

It should be noted that the light sensor modules of Examples 18 and 40 have similar structures and contents. The difference is that: the reflective layer of Example 40 includes polytetrafluoroethane (the ultraviolet reflective fillers), whereas the reflective layer of Example 18 is without polytetrafluoroethane

From results of Tables 5 and 8, the electric current generated by the photodiode chip in Example 18 can reach 85.1% of the target value, and the electric current generated by the photodiode chip in Example 40 can reach 92.4% of the target value. Accordingly, the addition of the ultraviolet reflective fillers into the reflective layer can increase the electric current generated by the photodiode chip, thereby reaching 90% to 100% of the target value.

[Control Group 3]

In order to compare the sensitivity of the light sensor module, another visible light-emitting diode is cooperated with another visible light photodiode (i.e., the photodiode chip 20 of the present disclosure), which form a light sensor module acting as Control Group 3. A visible light generated by the visible light-emitting diode is received by the visible light photodiode, and then an electric current is generated by the visible light photodiode. After experimentation, the visible light photodiode generates an electric current of 4.824 μA, which is taken as a target value of 100%.

### Seventh Embodiment

Referring to FIG. 8, the light sensor module 1 of the seventh embodiment is similar to the light sensor module 1 of the sixth embodiment (FIG. 7). The difference is that the wavelength conversion structure 30 of the seventh embodiment includes an encapsulating layer 34, a fluorescent layer 35, and a light-permeable substrate 36. The encapsulating layer 34 is disposed between the photodiode chip 20 and the fluorescent layer 35. The fluorescent layer 35 is formed on the light-permeable substrate 36 and contacts the encapsulating layer 34.

A material of the encapsulating layer 34 includes the encapsulating material 31 and the silicone powder 33. The encapsulating material 31 can be phenyl silicone resin or methyl silicone resin, and preferably is methyl silicone resin. The silicone powder 33 is uniformly dispersed in the encapsulating material 31. It should be noted that the silicone powder 33 is an optional component. In other words, the silicone powder 33 can be selectively present in or absent from the material of the encapsulating layer 34.

A material of the fluorescent layer 35 includes an encapsulating material 31 and the fluorescent material 32. The encapsulating material 31 in the fluorescent layer 35 can be the same or different from the encapsulating material 31 in the encapsulating layer 34. Accordingly, the encapsulating material 31 in the fluorescent layer 35 can be phenyl silicone resin or methyl silicone resin, and preferably is methyl silicone resin. The fluorescent material 32 is uniformly dispersed in the encapsulating material 31.

A material of the light-permeable substrate 36 can be quartz, glass, or other light-permeable materials. Therefore, ultraviolet light (the first light beam) can pass through the light-permeable substrate 36 and then be converted into visible light (the second light beam) by the fluorescent layer 35. Subsequently, the visible light (the second light beam) can pass through the encapsulating layer 34 and then be received by photodiode chip 20.

[Samples 1 and 2]

In order to increase a transmittance of the light sensor module, two different kinds of methyl silicone resin (methyl silicone resin A and methyl silicone resin B) are tested as the encapsulating material used in the fluorescent layer 35. The two kinds of methyl silicone resin are each coated on a quartz substrate (the light-permeable substrate 36) so as to obtain Samples 1 and 2. Transmittances of the Samples 1 and 2 and a transmittance of a (non-coated) quartz substrate are measured at wavelengths of 275 nm, 308 nm, and 365 nm. Results of the transmittances are listed in Table 9.

TABLE 9

| | | Transmittance | | |
|---|---|---|---|---|
| | Coating | 275 nm | 308 nm | 365 nm |
| Quartz substrate | None | 88.6% | 89.0% | 89.7% |
| Sample 1 | Methyl silicone | 79.7% | 81.3% | 82.8% |
| | resin A | | | |
| Sample 2 | Methyl silicone | 50.5% | 56.5% | 63.1% |
| | resin B | | | |

Accordingly to Table 9, Sample 1 has a higher transmittance at a wavelength of 275 nm. Therefore, methyl silicone resin A can be used as the encapsulating material used in the fluorescent layer, such that more ultraviolet light can be detected by the light sensor module. In an exemplary embodiment, the transmittance of the encapsulating material used in the fluorescent layer is higher than 70% at a wavelength of 275 nm. Preferably, the transmittance of the encapsulating material used in the fluorescent layer ranges from 70% to 88%.

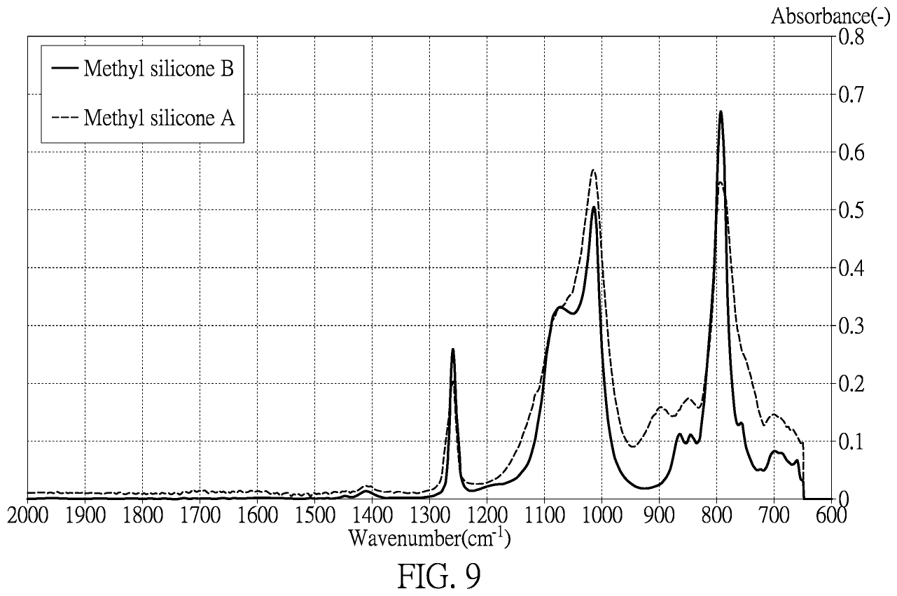

In addition, the two different kinds of methyl silicone resin (methyl silicone resin A and methyl silicone resin B) are measured by a Fourier transform infrared spectroscopy (FTIR). FTIR spectra of the methyl silicone resin A and the methyl silicone resin B (after being cured) are shown in FIG. 9.

Referring to FIG. 9, the methyl silicone resin A and the methyl silicone resin B both contain a difunctional resin and a composite resin having a monofunctional structure and a tetrafunctional structure. A structural unit of the difunctional resin includes a difunctional structure (R₂—Si—O_{2/2}). Structural units of the composite resin include a monofunctional structure (R₃—Si—O_{1/2}) and a tetrafunctional structure (Si—O_{4/2}). Specific structural units are shown in Table 10. Due to the structural units shown in Table 10, the difunctional resin has a linear structure, and the composite resin has a network structure.

TABLE 10

| | |
|---|---|
| 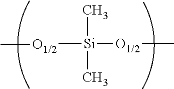 | Difunctional structure |
| 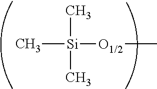 | Monofunctional structure |
| 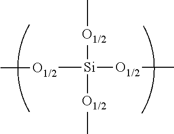 | Tetrafunctional structure |

Referring to FIG. 9, the methyl silicone resin A contains 70 wt % to 80 wt % of the difunctional resin and 20 wt % to 30 wt % of the composite resin.

### Examples 41 and 42

The light sensor module of Examples 41 and 42 corresponds to the light sensor module of the seventh embodiment (FIG. 8). Referring to Table 11, the encapsulating layer of Example 41 contains the silicone powder; while the encapsulating layer of Example 42 does not contain the silicone powder 42. In Example 41, based on a total weight of the encapsulating material used in the encapsulating layer being 100 phr, the content of the silicone powder in Example 41 is 80 phr.

In Examples 41 and 42, the encapsulating material used in the encapsulating layer, the encapsulating material used in the fluorescent layer, and the encapsulating material used in the reflective layer are the methyl silicone resin A. The fluorescent material used in the fluorescent layer is Tb₃Al₅O₁₂:Ce³⁺. Based on a total weight of the encapsulating material in the fluorescent layer being 100 phr, the content of the fluorescent material is 40 phr.

The material of the reflective layer includes the encapsulating material, the visible light reflective fillers (titanium dioxide), and the ultraviolet reflective fillers (polytetrafluoroethane) Based on a total weight of the encapsulating material and the visible light reflective fillers used in the reflective layer being 100 wt %, the content of the visible light reflective fillers is 20 wt % to 50 wt %. Based on the total weight of the encapsulating material and the visible light reflective fillers used in the reflective layer being 100 phr, the content of the ultraviolet reflective fillers is 80 phr.

In Examples 41 and 42, the light sensor module is exposed to ultraviolet light, and then the electric current generated by the photodiode chip is measured. The electric current is compared to the electric current of Control Group 3 designated as the target value of 100%.

TABLE 11

| | | | Encapsulating | | |
|---|---|---|---|---|---|
| | Fluorescent layer | | layer | | |
| | | Content of | Content of | Photodiode chip | |
| | Fluorescent | fluorescent | silicone | Electric | Target |
| | material | material | powder | current | value |
| Example | Tb₃Al₅O₁₂:Ce³⁺ | 40 phr | 80 phr | 4.954 μA | 103% |
| 41 | | | | | |
| Example | Tb₃Al₅O₁₂:Ce³⁺ | 40 phr | 0 phr | 5.027 μA | 104% |
| 42 | | | | | |

From results of Table 11, the sensitivity of the light sensor module of the seventh embodiment is slightly influenced by an addition of the silicone powder. Therefore, the addition of the silicone powder is optionally in the light sensor module of the seventh embodiment. In a preferable embodiment, the silicone powder is absent from the encapsulating layer.

Based on the total weight of the encapsulating material used in the fluorescent layer being 100 phr, the content of the fluorescent material ranges from 20 phr to 60 phr. Preferably, based on the total weight of the encapsulating material used in the fluorescent layer being 100 phr, the content of the fluorescent material ranges from 30 phr to 50 phr.

From results of Tables 8 and 11, the electric current generated by the photodiode chip in Example 40 reaches 92.4% of the target value, and the electric current generated by the photodiode chip in Example 41 reaches 103% of the target value. Therefore, due to a structure of the light sensor module of the seventh embodiment, the sensitivity of the light sensor module can be enhanced to reach a higher target value.

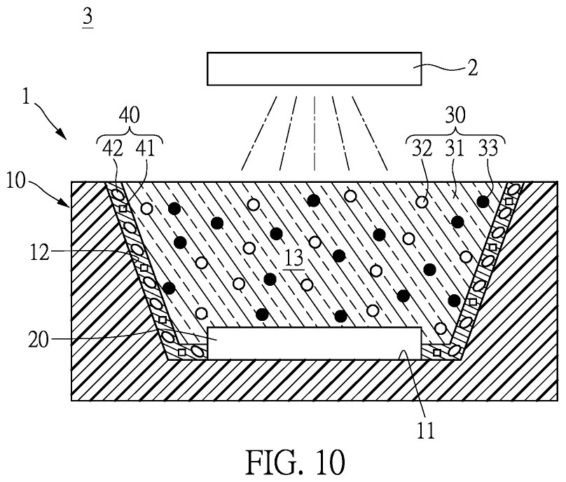

Referring to FIG. 10, the present disclosure provides an electronic device 3. The electronic device 3 includes a light-emitting module 2 and the aforesaid light sensor module 1. The light-emitting module 2 can generate a first light beam. The light sensor module 1 can receive the first light beam, and then generate an electric current corresponding to an intensity of the first light beam. Specifically, the light sensor module 1 includes the aforesaid substrate 10, the aforesaid photodiode chip 20, and the aforesaid wavelength conversion structure 30. The specific structure of the light sensor module 1 is as described in the previous embodiments, and will not be repeated herein. Specifically, the light-emitting module 2 includes a light-emitting chip which can generate the first light beam.

In some embodiments, the light-emitting module 2 can generate ultraviolet light (the first light beam). In other words, the first light beam has a peak wavelength ranging between 10 nm to 400 nm. The first light beam can be converted into the visible light (the second light beam) by the wavelength conversion structure 30 of the light sensor module 1. In other words, the second light beam has a spectrum ranging between 400 nm to 700 nm. Subsequently, after receiving the second light beam, the photodiode chip 20 generates an electric current corresponding to an intensity of the second light beam.

### Beneficial Effects of the Embodiments

In conclusion, by virtue of “the first light beam being converted into a second light beam by the wavelength conversion structure 30” and “the photodiode chip 20 receiving the second light beam and then generating the electric current”, the cost of the light sensor module 1 of the present disclosure can be reduced.

Further, by virtue of “the wavelength conversion structure 30 including an encapsulating material 31, and the encapsulating material 31 being methyl silicone resin, phenyl silicone resin, or fluorosilicone resin”, the sensitivity of the light sensor module 1 can be enhanced.

Further, by virtue of “the second light beam having a spectrum ranging between 453 nm to 647 nm” and “the second light beam having a spectrum ranging between 465 nm to 625 nm”, the sensitivity of the light sensor module 1 can be enhanced.

Further, by virtue of “a material of the wavelength conversion structure 30 including a silicone powder 33”, the sensitivity of the light sensor module 1 can be enhanced.

Further, by virtue of “a material of the reflective layer 40 including visible light reflective fillers 41” and “a material of the reflective layer 40 including ultraviolet reflective fillers 42”, the sensitivity of the light sensor module 1 can be enhanced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light sensor module, being used to receive a first light beam and generate an electric current corresponding to an intensity of the first light beam, the light sensor module comprising:
a substrate;
a photodiode chip disposed on the substrate; and
a wavelength conversion structure disposed on the substrate, the photodiode chip being covered by the wavelength conversion structure;
wherein the first light beam is converted into a second light beam by the wavelength conversion structure, and the photodiode chip receives the second light beam and then generates the electric current.

2. The light sensor module according to claim 1, wherein the first light beam has a peak wavelength ranging between 10 nm and 400 nm.

3. The light sensor module according to claim 1, wherein the second light beam has a spectrum ranging between 400 nm and 700 nm.

4. The light sensor module according to claim 1, wherein a material of the wavelength conversion structure includes an encapsulating material, and the encapsulating material is methyl silicone resin, phenyl silicone resin, or fluorosilicone resin.

5. The light sensor module according to claim 1, wherein a material of the wavelength conversion structure includes a fluorescent material and an encapsulating material.

6. The light sensor module according to claim 5, wherein, based on a total weight of the encapsulating material used in the wavelength conversion structure being 100 phr, a content of the fluorescent material ranges from 5 phr to 80 phr.

7. The light sensor module according to claim 5, wherein the fluorescent material is selected from the group consisting of: a metal oxide containing rare earth elements, a metal nitride containing rare earth elements, a metal phosphide containing rare earth elements, a metal silicon oxide containing rare earth elements, a metal oxynitride containing rare earth elements, a metal oxycarbonitride containing rare earth elements, and any combination thereof.

8. The light sensor module according to claim 1, wherein a material of the wavelength conversion structure includes silicone powder and an encapsulating material.

9. The light sensor module according to claim 8, wherein, based on a total weight of the encapsulating material used in the wavelength conversion structure being 100 phr, a content of the silicone powder is more than or equal to 40 phr.

10. The light sensor module according to claim 8, wherein a microstructure is formed on a surface of the wavelength conversion structure.

11. The light sensor module according to claim 1, wherein the wavelength conversion structure includes a fluorescent layer and an encapsulating layer, and the encapsulating layer is disposed between the fluorescent layer and the photodiode chip.

12. The light sensor module according to claim 11, wherein the encapsulating material is methyl silicone resin, and a transmittance of the methyl silicone resin is higher than 70% at a wavelength of 275 nm.

13. The light sensor module according to claim 11, wherein the fluorescent layer is formed on a light-permeable substrate, and a material of the fluorescent layer includes an encapsulating material and a fluorescent material.

14. The light sensor module according to claim 13, wherein, based on a total weight of the encapsulating material used in the fluorescent layer being 100 phr, a content of the fluorescent material ranges from 20 phr to 60 phr.

15. The light sensor module according to claim 11, wherein a material of the encapsulating layer includes an encapsulating material, and the encapsulating material is methyl silicone resin.

16. The light sensor module according to claim 15, wherein, based on a total weight of the methyl silicone resin being 100 wt %, the methyl silicone resin contains 70 wt % to 80 wt % of a difunctional resin and 20 wt % to 30 wt % of a composite resin having a monofunctional structure and a tetrafunctional structure.

17. The light sensor module according to claim 1, wherein the substrate has a mounting surface and an inner side surface connected to each other, an accommodation space is formed between the mounting surface and the inner side surface, and the photodiode chip is disposed in the accommodation space and arranged between the substrate and the wavelength conversion structure.

18. The light sensor module according to claim 17, further comprising a reflective layer disposed on the mounting surface or the inner side surface.

19. The light sensor module according to claim 18, wherein a material of the reflective layer includes an encapsulating material and visible light reflective fillers, and the visible light reflective fillers are selected from the group consisting of: titanium dioxide, aluminum oxide, zinc oxide, silicon dioxide, boron nitride, and any combination thereof.

20. The light sensor module according to claim 19, wherein, based on a total weight of the encapsulating material used in the reflective layer being 100 phr, a content of the visible light reflective fillers ranges from 20 phr to 50 phr.

21. The light sensor module according to claim 18, wherein a material of the reflective layer includes an encapsulating material and ultraviolet reflective fillers, and the ultraviolet reflective fillers are selected from the group consisting of: polytetrafluoroethene, zirconium dioxide, aluminum nitride, silicon dioxide, and any combination thereof.

22. The light sensor module according to claim 21, wherein, based on a total weight of the encapsulating material used in the reflective layer being 100 phr, a content of the ultraviolet reflective fillers ranges from 10 phr to 80 phr.

23. The light sensor module according to claim 22, wherein, based on the total weight of the encapsulating material used in the reflective layer being 100 phr, the content of the ultraviolet reflective fillers is more than or equal to 40 phr.

24. The light sensor module according to claim 18, wherein the reflective layer is disposed on both the mounting surface and the inner side surface.

25. The light sensor module according to claim 1, wherein the light sensor module is used in an ultraviolet sensor.
